(19) United States
(12) Patent Application Publication
(10) Pub. No.: US 2026/0327779 A1
(43) Pub. Date: Oct. 22, 2026

(54) DEPOSITION MASK AND METHOD FOR MANUFACTURING DEPOSITION MASK

(71) Applicant: Samsung Display Co., LTD., Yongin-si (KR)

(72) Inventors: ILSUP KIM, Yongin-si (KR); INSOO PARK, Yongin-si (KR)

(21) Appl. No.: 19/455,422

(22) Filed: Jan. 21, 2026

(30) Foreign Application Priority Data
Apr. 22, 2025 (KR) 10-2025-0052543

(51) Int. Cl. C23C 14/04; H10K 71/16

(52) U.S. Cl. CPC C23C 14/042; H10K 71/166

(57) ABSTRACT

A deposition mask includes a base layer, a protective layer, and a pattern layer. The base layer has an opening defined therein corresponding to a transmission region. The protective layer is disposed on the base layer and has an opening defined therein overlapping the transmission region. The pattern layer is disposed on the protective layer and includes a pattern grid overlapping the transmission region. An area of a lower surface of the pattern grid adjacent to the protective layer is smaller than an area of an upper surface of the pattern grid opposite to the lower surface. The pattern layer includes at least one selected from monocrystalline silicon and polycrystalline silicon.

### CROSS-REFERENCE TO RELATED APPLICATION

This application claims priority to Korean Patent Application No. 10-2025-0052543, filed on Apr. 22, 2025, and all the benefits accruing therefrom under 35 U.S.C. §119, the content of which is incorporated herein in its entirety by reference.

### BACKGROUND

### 1. Field

The present disclosure relates to a deposition mask and a method for manufacturing the deposition mask. Specifically, the disclosure relates to a deposition mask with improved deposition precision and a method for manufacturing such a deposition mask.

### 2. Description of the Related Art

In order to implement ultra-compact and high-resolution display devices, organic light-emitting diode (OLED)-on-silicon (OLEDoS) technology has been developed, in which an OLED is disposed on a silicon (Si) substrate. In the fabrication of OLED pixels, a deposition process is performed by evaporating and depositing light-emitting materials onto the substrate. To this end, a fine pattern mask is used to ensure that the light-emitting material is deposited accurately at a target location. As one type of fine pattern mask, a fine metal mask (FMM), fabricated from a metallic material such as a nickel (Ni) alloy or Invar, is mainly used.

In a high-resolution display device, however, with the decreasing size of the pixels to be implemented and the increasing precision requirement, a silicon-wafer-based fine silicon mask (FSM) is employed. The FSM allows precise pattern processing based on silicon and has a low coefficient of thermal expansion (CTE), thereby minimizing deformation during the deposition process.

### SUMMARY

The present disclosure provides a deposition mask with minimum shadow effects caused by the mask during deposition and a method for manufacturing such a deposition mask.

In addition, the disclosure provides a deposition mask with improved deposition precision by fabricating a mask pattern grid including silicon (Si) in an inverted taper shape and a method for manufacturing such a deposition mask.

According to an embodiment of the disclosure, a deposition mask includes a base layer, a protective layer, and a pattern layer. In such an embodiment, the base layer has an opening defined therein corresponding to a transmission region. In such an embodiment, the protective layer is disposed on the base layer and has an opening defined therein overlapping the transmission region. In such an embodiment, the pattern layer is disposed on the protective layer and includes a pattern grid overlapping the transmission region. In such an embodiment, an area of a lower surface of the pattern grid adjacent to the protective layer is smaller than an area of an upper surface of the pattern grid opposite to the lower surface. In such an embodiment, the pattern layer includes at least one selected from monocrystalline silicon and polycrystalline silicon.

In an embodiment, a width of the pattern grid may increase as being away from the protective layer.

In an embodiment, the base layer may include silicon.

In an embodiment, an area of an upper surface of the base layer adjacent to the protective layer may be larger than an area of a lower surface of the base layer facing the protective layer with the upper surface of base layer therebetween.

In an embodiment, the protective layer may include silicon oxide (SiOₓ).

In an embodiment, an area of an upper surface of the protective layer adjacent to the pattern layer may be larger than an area of a lower surface of the protective layer adjacent to the base layer.

In an embodiment, the deposition mask may further include a lower layer disposed below the base layer and having an opening defined therein overlapping the transmission region.

In an embodiment, the lower layer may include silicon oxide (SiOₓ).

A method for manufacturing a deposition mask according to an embodiment of the present disclosure includes: preparing a base substrate including silicon; forming a mask body by depositing a first protective layer surrounding the base substrate, an intermediate layer surrounding the first protective layer and comprising at least one selected from monocrystalline silicon and polycrystalline silicon, and a second protective layer surrounding the intermediate layer; forming a pattern grid by etching the second protective layer and the intermediate layer formed on a first side of the mask body; performing a first etching process to remove the second protective layer and the intermediate layer formed on a second side of the mask body opposite to the first side with the base substrate therebetween; forming a mask opening overlapping the pattern grid by etching the first protective layer and the base substrate from the second side; and performing a second etching process to remove the second protective layer remaining on the first side.

In an embodiment, the forming the pattern grid may include dry etching the second protective layer and the intermediate layer using a Bosch etching process.

In an embodiment, in the forming the pattern grid, the pattern grid may be formed in a way such that an area of an upper surface of the pattern grid adjacent to the first side of the mask body is larger than an area of a lower surface of the pattern grid adjacent to the base substrate.

In an embodiment, the method may further include coating a photoresist onto the first side of the mask body and performing exposure and development processes between the forming the mask body and the forming the pattern grid.

In an embodiment, the forming the mask opening may include using a wet etching process.

In an embodiment, in the forming the mask opening, the mask opening may be formed in a way such that an area of an upper surface of the base substrate adjacent to the pattern grid is larger than an area of a lower surface of the base substrate adjacent to the second side of the mask body.

In an embodiment, the second protective layer may include silicon nitride (SiNₓ).

In an embodiment, in the forming the mask body, the second protective layer may be deposited to be thinner than the intermediate layer.

In an embodiment, in the forming the mask body, the second protective layer may be deposited to have a thickness greater than or equal to about 400 angstrom (Å) and smaller than or equal to about 500 Å.

In an embodiment, the performing the first etching process may include removing the first protective layer formed on the second side of the mask body, and the forming the mask opening may include etching the first protective layer formed on the first side.

In an embodiment, performing the second etching process may include removing the second protective layer using a wet etching process.

In an embodiment, the first protective layer may include silicon oxide (SiOₓ).

According to embodiments of the present disclosure, since the mask pattern layer includes silicon (Si), the pattern grid may be more readily etched in an inverted taper shape.

In addition, according to embodiments of the disclosure, deposition precision may be improved, and shadow effects caused by the deposition mask may be reduced.

### BRIEF DESCRIPTION OF THE DRAWINGS

These and/or other features of embodiments will become apparent and more readily appreciated from the following description of the embodiments, taken in conjunction with the accompanying drawings, in which:

FIG. 1 is a top plan view schematically illustrating a deposition mask according to an embodiment of the present disclosure;

FIG. 2 is a cross-sectional view schematically illustrating a deposition mask according to an embodiment of the present disclosure;

FIG. 3 is an enlarged view of region AA shown in FIG. 2;

FIG. 4 is an image of a pattern grid fabricated according to an embodiment of the present disclosure;

FIG. 5 is a cross-sectional view schematically illustrating a display panel manufactured according to an embodiment of the present disclosure;

FIG. 6 is a flowchart illustrating a method for manufacturing a deposition mask according to an embodiment of the present disclosure; and

FIGS. 7A-7I are cross-sectional views schematically illustrating respective steps of the method for manufacturing a deposition mask according to an embodiment of the present disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

When an element (or region, layer, portion, or the like) is described to be “disposed on,” “placed on,” “arranged on,” “connected to,” or “coupled to” another element, it shall be construed as being disposed on, placed on, arranged on, connected to, or coupled to the other element directly but also as possibly having another element therebetween. When one element is described to be “directly disposed on,” “directly placed on,” “directly arranged on,” “directly connected to,” or “directly coupled to” another element, it shall be construed that there is no other element interposed therebetween.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements. As such, the disclosure shall not be restricted to the thicknesses, ratios, dimensions, characteristics, and the like illustrated in the drawings.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

"About" or "approximately" as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, "about" can mean within one or more standard deviations, or within ± 30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In the specification, when any embodiment may be differently implemented, the specified order of process may be performed differently than the described order. In an embodiment, two processes described to be performed sequentially may be performed simultaneously or performed in a reverse order, for example.

In the disclosure, for the purpose of describing a deposition mask in an embodiment, first through third directions DR1, DR2, DR3 may be defined. The deposition mask is disposed on a plane defined by the first direction DR1 and the second direction DR2. The third direction DR3 is defined as the thickness direction of the deposition mask, and the first through third directions DR1, DR2, DR3 may be mutually orthogonal.

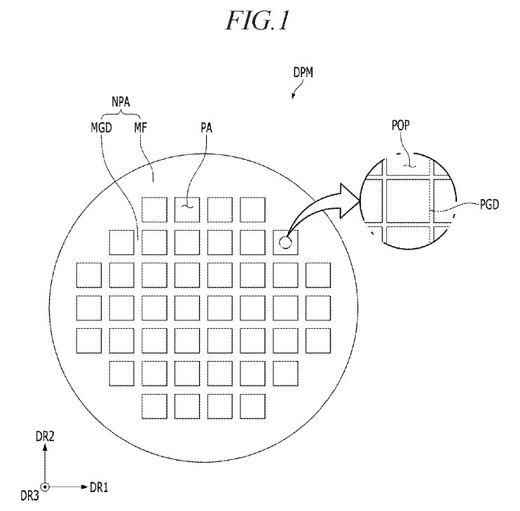

FIG. 1 is a top plan view schematically illustrating a deposition mask DPM according to an embodiment of the present disclosure. Referring to FIG. 1, the deposition mask DPM may include a non-transmission region NPA and a transmission region PA. The non-transmission region NPA may have a shape that surrounds the transmission region PA. The non-transmission region NPA may include a mask frame MF and a mask grid MGD.

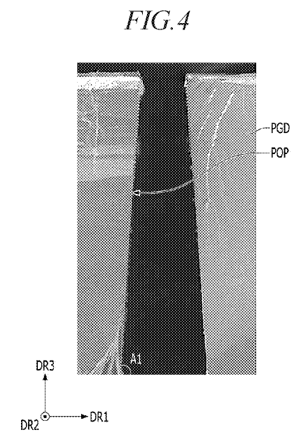

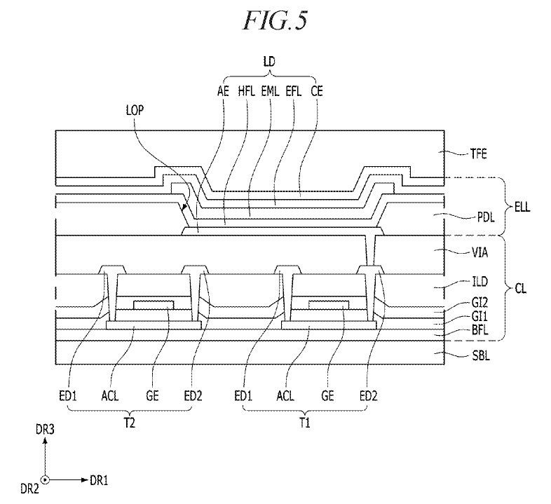

In an embodiment, the deposition mask DPM may be configured to allow a deposition material to be deposited at specific locations on a substrate (not shown) during a deposition process. The detailed configuration of the substrate onto which the deposition material is deposited through the deposition mask DPM will be described later with reference to FIG. 5.

The mask frame MF may form an outer portion of the deposition mask DPM. In an embodiment, as shown in FIG. 1, the mask frame MF may have a circular shape, but it is not limited thereto.

The transmission region PA or an opening corresponding to the transmission region PA may be defined by the mask grid MGD. The deposition material may be blocked by the mask grid MGD during the deposition process.

A pattern grid PGD may be formed within the transmission region PA. A pattern opening POP may be defined by the pattern grid PGD within the transmission region PA. The shapes of the pattern grid PGD and the pattern opening POP are not limited to those illustrated in FIG. 1. The deposition material may pass through the pattern opening POP.

The opening corresponding to the transmission region PA and the pattern opening POP defined by the pattern grid PGD may be defined by or formed in different layers of the deposition mask DPM. The opening corresponding to the transmission region PA and the pattern opening POP will be described in detail later.

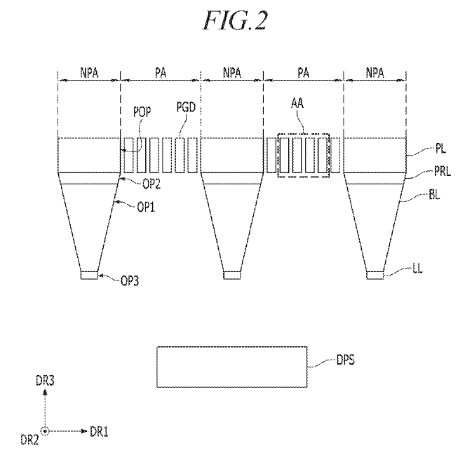

FIG. 2 is a cross-sectional view schematically illustrating a deposition mask DPM according to an embodiment of the present disclosure. Referring to FIG. 2, the deposition mask DPM may include a base layer BL, a protective layer PRL, a pattern layer PL, and a lower layer LL. The materials forming the deposition mask DPM and the stacked structure of the deposition mask DPM are not limited thereto.

The base layer BL may have a first opening OP1 defined therein corresponding to a transmission region PA. Deposition material emitted from a deposition source DPS in a third direction DR3 may reach a substrate (not shown) through the first opening OP1. The substrate may be disposed adjacent to the pattern layer PL. An area of an upper surface of the base layer BL adjacent to the protective layer PRL may be larger than an area of a lower surface of the base layer BL. Accordingly, in a cross-sectional view or in a plane defined by the first direction DR1 and the third direction DR3, the base layer BL may have an inverted taper shape, in which the upper surface is larger than the lower surface. In the cross-sectional view or in the same plane defined by the first direction DR1 and the third direction DR3, the first opening OP1 may have a tapered shape such that the size of the first opening OP1 is larger at the lower surface of the base layer BL than at the upper surface of the base layer BL.

In an embodiment of the present disclosure, the base layer BL may include silicon. Accordingly, the deposition mask DPM (see FIG. 1) may be a fine silicon mask (FSM) in which a mask pattern (or mask membrane) is formed on a silicon wafer substrate. By including silicon in the base layer BL, the precision of mask pattern processing may be improved. The deposition mask DPM according to an embodiment of the present disclosure may be used in manufacturing an organic light emitting diode (OLED) on Silicon (OLEDoS) panel having high-resolution pixels.

The protective layer PRL may be disposed on the base layer BL. A second opening OP2, overlapping the transmission region PA, may be defined in the protective layer PRL. The second opening OP2 may extend from or be connected to the first opening OP1. That is, deposition material emitted from the deposition source DPS in the third direction DR3 may reach the substrate through the first opening OP1 and the second opening OP2. An area of an upper surface of the protective layer PRL adjacent to the pattern layer PL may be larger than an area of a lower surface of the protective layer PRL adjacent to the base layer BL. Accordingly, in a cross-sectional view or in a plane defined by the first direction DR1 and the third direction DR3, the protective layer PRL may have an inverted taper shape, in which the upper surface is larger than the lower surface. In the same plane defined by the first direction DR1 and the third direction DR3, the second opening OP2 may have a tapered shape such that the size of the second opening OP2 is larger at the lower surface of the protective layer PRL than at the upper surface of the protective layer PRL.

In an embodiment, the protective layer PRL may include silicon oxide (SiOₓ). The protective layer PRL may function to protect the base layer BL from being excessively etched during the manufacturing of the deposition mask DPM. In such an embodiment, the protective layer PRL may improve the uniformity of the pattern layer PL deposited the protective layer PRL and minimize surface defects. The protective layer PRL may also enhance adhesion of the pattern layer PL and interfacial stability with the base layer BL.

The pattern layer PL may be disposed on the protective layer PRL. The pattern layer PL may include a pattern grid PGD overlapping the transmission region PA. A pattern opening POP may be defined by the pattern grid PGD within the transmission region PA. The pattern layer PL may function as a membrane of the deposition mask DPM. The pattern grid PGD may be configured to allow deposition material emitted from the deposition source DPS in the third direction DR3 to pass through the pattern opening POP and deposit only at specific locations on the substrate. That is, the deposition material may be blocked by the pattern grid PGD.

The deposition process may be performed while the substrate is positioned to face the deposition source DPS with the deposition mask DPM interposed between the deposition source DPS and the substrate. When deposition material passes through the pattern opening POP in the third direction DR3 and deposits on the substrate, the shape of the pattern grid PGD may influence deposition precision. If the shape of the pattern grid PGD causes a shadow effect, deposition material may fail to deposit in the targeted deposition region.

In an embodiment where the pattern grid PGD is formed in an inverted taper shape, that is, a surface of the pattern grid PGD adjacent to the substrate is larger than a surface of the pattern grid PGD adjacent to the deposition source DPS, the shadow effect may be minimized. Here, the pattern opening POP may be formed in a tapered shape such that the size of the pattern opening POP increases toward the deposition source DPS. As a result, the deposition area relative to the deposition source DPS may be widened, thereby reducing the shadow region.

In a conventional deposition mask, the pattern layer often includes silicon nitride (SiNₓ), which is deposited by low-pressure chemical vapor deposition (LP CVD). Consequently, the pattern layer may be formed as a low-stress nitride (LSN) film. Due to its high density and strong bond energy, the low-stress nitride exhibits high etch resistance and thus may be desired to use a high bias voltage during the etching process. Therefore, since isotropic etching would be difficult for the low-stress nitride, it may be difficult to implement the pattern grid PGD in an inverted taper shape.

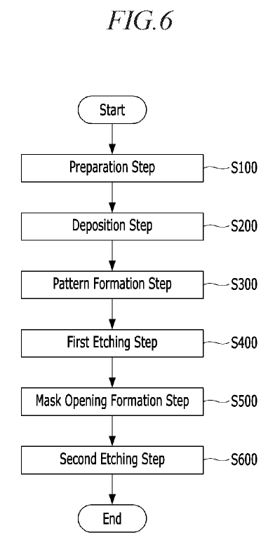

In an embodiment, the pattern layer PL may include at least one selected from monocrystalline silicon (Si) and polycrystalline silicon (Poly-Si). The pattern layer PL may include or be formed of a same material as the base layer BL. Monocrystalline silicon or polycrystalline silicon exhibits high chemical reactivity with SF₆ plasma. In addition, when monocrystalline silicon or polycrystalline silicon is etched using a Bosch etching process, it is possible to form hole patterns having a high aspect ratio. Therefore, a pattern layer PL including or formed of monocrystalline silicon or polycrystalline silicon may be more easily etched in an inverted taper shape during dry etching. A method for fabricating the pattern grid PGD will be described later with reference to FIG. 6.

As a result, in an embodiment where the pattern layer PL is formed to include at least one selected from monocrystalline silicon (Si) and polycrystalline silicon (Poly-Si), the pattern grid PGD may be fabricated in an inverted taper shape. Accordingly, an area of a lower surface of the pattern grid PGD adjacent to the protective layer PRL may be smaller than an area of an upper surface of the pattern grid PGD. The width of the pattern grid PGD may increase with distance (or as being away) from the protective layer PRL.

The lower layer LL may be disposed below the base layer BL. A third opening OP3, overlapping the transmission region PA, may be defined in the lower layer LL. The third opening OP3 may extend from the first opening OP1. That is, deposition material emitted from the deposition source DPS in the third direction DR3 may reach the substrate through the first to third openings OP1 to OP3.

In an embodiment, the lower layer LL may include silicon oxide (SiOₓ). The lower layer LL may function to protect the base layer BL from being excessively etched during the manufacturing of the deposition mask DPM. The lower layer LL may include or be formed of a same material as the protective layer PRL.

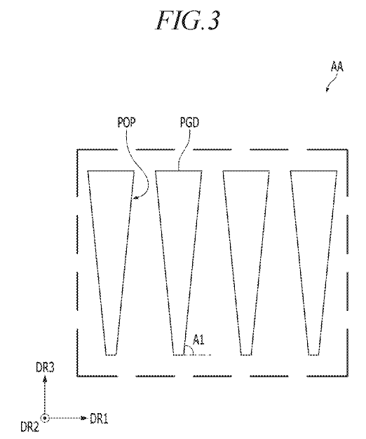

FIG. 3 is an enlarged view schematically illustrating region AA shown in FIG. 2. In FIG. 3, a cross-sectional view of the pattern grid PGD is schematically illustrated. The shadow region, where deposition material is not deposited on the substrate, may be determined based on a taper angle A1 of the pattern grid PGD. Here, the taper angle A1 may be defined as the angle formed between an upper surface of the pattern grid PGD and a side surface of the pattern grid PGD. In other words, the taper angle A1 may be the angle formed between a side surface of the pattern grid PGD inclined relative to the third direction DR3 and a plane of the pattern opening POP defined by the first direction DR1 and the second direction DR2. In an embodiment, for example, the taper angle A1 of the pattern grid PGD for minimizing the shadow effects may be greater than or equal to about 80° and smaller than or equal to about 85°.

In an embodiment of the present disclosure, the pattern grid PGD including at least one selected from monocrystalline silicon (Si) and polycrystalline silicon (Poly-Si) may be etched in an inverted taper shape. In an embodiment, for example, the taper angle A1 of the pattern grid PGD may be greater than or equal to about 80° and smaller than about 90°. Since the surface area of the pattern grid PGD adjacent to the deposition source is smaller than the surface area of the pattern grid PGD adjacent to the substrate, the shadow region on the substrate may be reduced.

FIG. 4 is an image of a pattern grid fabricated according to an embodiment of the present disclosure. Referring to FIG. 4, the pattern grid PGD may be etched in an inverted taper shape, and a pattern opening POP formed by etching may have a tapered shape. The taper angle A1 of the pattern grid PGD may be greater than or equal to about 80° and smaller than about 90°. Deposition material emitted from a deposition source may reach the substrate along the third direction DR3 through the pattern opening POP. Since the pattern grid PGD has an inverted taper shape, the shadow effects may be minimized, and the deposition precision may be improved.

FIG. 5 is a cross-sectional view schematically illustrating a display panel manufactured according to an embodiment of the present disclosure. Referring to FIG. 5, the display panel may include a base member SBL, a circuit layer CL, a light-emitting element layer ELL, and an encapsulation layer TFE. The base member SBL and the circuit layer CL may include a plurality of transistors T1, T2. The structures of the first transistor T1 and the second transistor T2 are not limited thereto. Some of the components of the display panel DP illustrated in FIG. 5 may be formed through a deposition process using the deposition mask DPM described with reference to FIG. 1.

The base member SBL may include a semiconductor wafer. in an embodiment, for example, the base member SBL may include a silicon wafer, a compound semiconductor wafer, a silicon carbide wafer, a sapphire wafer, a diamond wafer, or the like. The base member SBL may include part of the plurality of transistors T1, T2.

The circuit layer CL may include a buffer layer BFL, first and second gate insulating layers GI1, GI2, an interlayer insulating layer ILD, a circuit insulating layer VIA, and other parts of the plurality of transistors T1, T2. In an embodiment, for example, the circuit layer CL may include a control electrode GE, a first electrode ED1, and a second electrode ED2 that constitute each of the plurality of transistors T1, T2.

The buffer layer BFL may be configured to prevent impurities present in the base layer BL from penetrating into the pixels during the manufacturing process. In particular, the impurities may be effectively prevented from diffusing into active regions ACL of the plurality of transistors T1, T2 that constitute the pixels. Furthermore, the buffer layer BFL may serve to block moisture from entering the pixels from outside.

The active regions ACL may include a channel region serving as a passage through which electrons or holes move, and first and second ion-doped regions disposed on opposite sides of the channel region.

A first gate insulating layer GI1 covering the active regions ACL may be disposed on the buffer layer BFL. The first gate insulating layer GI1 may include at least one of an organic film and an inorganic film.

Control electrodes GE, which constitute each of the plurality of transistors T1, T2, may be disposed on the first gate insulating layer GI1. The control electrode GE of the first transistor T1 may correspond to one of two electrodes forming a capacitor.

A second gate insulating layer GI2 covering the control electrodes GE may be disposed on the first gate insulating layer GI1. The second gate insulating layer GI2 may include at least one selected from an organic film and an inorganic film.

Another one of the two electrodes forming the capacitor may be disposed on the second gate insulating layer GI2. However, the structure in which the electrodes forming the capacitor are disposed is not limited thereto.

An interlayer insulating layer ILD may be disposed on the second gate insulating layer GI2. The interlayer insulating layer ILD may cover the first and second gate insulating layers GI1, GI2 and the plurality of control electrodes GE. The interlayer insulating layer ILD may include at least one selected from an organic film and an inorganic film.

A plurality of first electrodes ED1 and a plurality of second electrodes ED2, which constitute each of the plurality of transistors T1, T2, may be disposed on the interlayer insulating layer ILD. The first electrodes ED1 and the second electrodes ED2 may each be electrically connected to corresponding active regions ACL through contact holes penetrating (or defined through) the first and second gate insulating layers GI1, GI2 and the interlayer insulating layer ILD.

A circuit insulating layer VIA covering the first electrodes ED1 and the second electrodes ED2 may be disposed on the interlayer insulating layer ILD. The circuit insulating layer VIA may include at least one selected from an organic film and an inorganic film and may provide a planar surface.

A pixel defining layer PDL may be disposed on a portion of the circuit insulating layer VIA. A light-emitting opening LOP may be defined by the pixel defining layer PDL. A light-emitting diode LD may be disposed or formed in the light-emitting opening LOP.

The light-emitting diode LD may include an anode electrode AE, a hole functional layer HFL, an emission layer EML, an electron functional layer EFL, and a cathode electrode CE. The light-emitting diode LD may emit light.

The anode electrode AE may be disposed on a portion of the circuit insulating layer VIA. In an embodiment, the anode electrode AE may be disposed in the light-emitting opening LOP and may be electrically connected to the second electrode ED2. Although FIG. 5 illustrate an embodiment where the second electrode ED2 of the first transistor T1 is in direct contact with the anode electrode AE, the present disclosure is not limited thereto.

The hole functional layer HFL may be disposed on the anode electrode AE. The hole functional layer HFL may assist the movement of holes generated at the anode electrode AE.

The emission layer EML may be disposed on the hole functional layer HFL and may be configured to emit light. In an embodiment, the emission layer EML may include an organic light-emitting material. In such an embodiment, the light-emitting diode LD may be an OLED.

The electron functional layer EFL may be disposed on the emission layer EML and may assist the movement of electrons generated at the cathode electrode CE.

The cathode electrode CE may be disposed on the electron functional layer EFL. The cathode electrode CE may have low resistance to facilitate current flow.

The encapsulation layer TFE may seal the light-emitting diode LD to protect the light-emitting diode LD from external oxygen and/or moisture. The encapsulation layer TFE may include a layer in which organic and inorganic films are mixed.

The deposition mask DPM (see FIG. 1) of the present disclosure may be used to form at least one selected from the first and second gate insulating layers GI1, GI2, the interlayer insulating layer ILD, the circuit insulating layer VIA, the emission layer EML, and the encapsulation layer TFE, which include organic materials. However, the configurations of the display panel that may be formed using the deposition mask DPM of the present disclosure are not limited thereto.

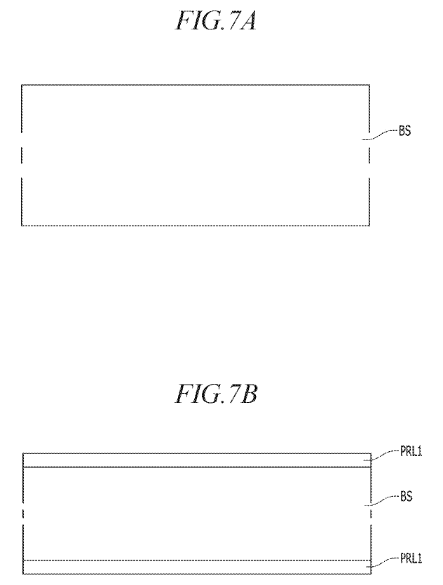

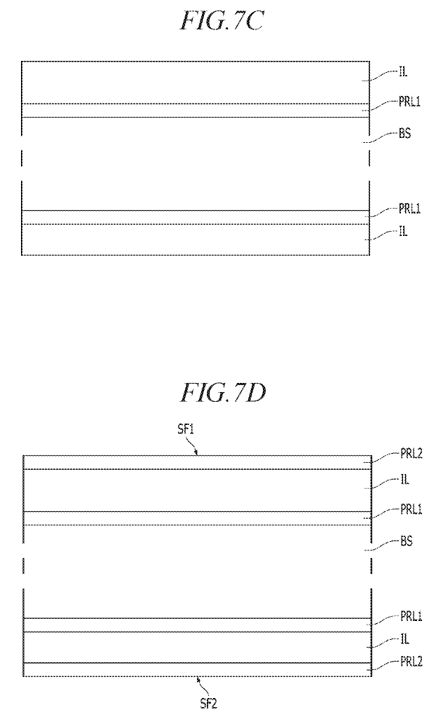

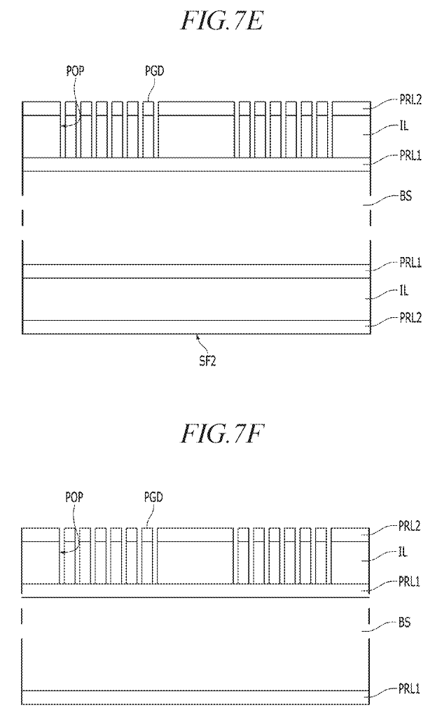

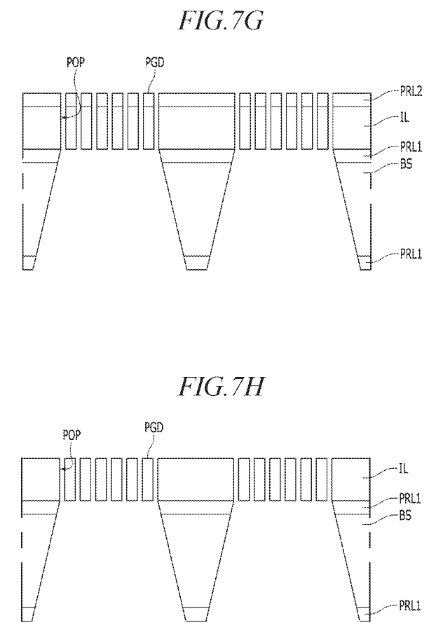

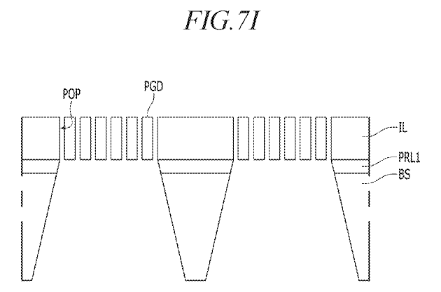

FIG. 6 is a flowchart illustrating a method for manufacturing a deposition mask according to an embodiment of the present disclosure. FIGS. 7A-7I schematically illustrate respective steps (processes or operations) of the method for manufacturing a deposition mask according to the present disclosure. FIGS. 7A-7I may be understood as cross-sectional views of the deposition mask. The method of FIG. 6 will be described with reference to FIGS. 7A-7I.

Referring to FIG. 6, an embodiment of the method for manufacturing a deposition mask may include a preparation step (S100), a deposition step (S200), a pattern formation step (S300), a first etching step (S400), a mask opening formation step (S500), and a second etching step (S600).

Referring to FIGS. 6 and 7A, in the preparation step (S100), a base substrate BS including silicon may be prepared. The base substrate BS may be a silicon wafer.

Referring to FIGS. 6 and 7B, in the deposition step (S200), a first protective layer PRL1 surrounding the base substrate BS may be deposited. The first protective layer PRL1 may include silicon oxide (SiOₓ). The first protective layer PRL1 may function to protect the base substrate BS from being excessively etched during the manufacturing of the deposition mask DPM.

In the deposition step (S200), prior to depositing an intermediate layer IL surrounding the first protective layer PRL1, additional processes may be performed to ensure uniform deposition of the intermediate layer IL and accurate alignment. Specifically, a photolithography process and an etching process may be performed to create alignment marks. To provide an accurate alignment reference, photoresist may be coated onto the base substrate BS, and exposure and development processes may be carried out to form a pattern for generating the alignment marks. In addition, at least a portion of the base substrate BS may be etched through the formed pattern. The base substrate BS may be etched using a reactive ion etching (RIE) process. As a result, alignment marks may be generated, and an optimal surface for depositing the intermediate layer IL may be prepared.

Referring to FIGS. 6 and 7C, in the deposition step (S200), an intermediate layer IL surrounding the first protective layer PRL1 may be deposited. The intermediate layer IL may include at least one selected from monocrystalline silicon (Si) and polycrystalline silicon (Poly-Si). The intermediate layer IL may include or be formed of a same material as the base substrate BS.

Referring to FIGS. 6 and 7D, in the deposition step (S200), a second protective layer PRL2 surrounding the intermediate layer IL may be deposited. The second protective layer PRL2 may include silicon nitride (SiNₓ). The silicon nitride may be deposited using a low-pressure chemical vapor deposition (LP CVD) process. Accordingly, the intermediate layer IL may be formed as a low-stress nitride film. The low-stress nitride film may function as a hard mask for protecting the intermediate layer IL.

In the deposition step (S200), the second protective layer PRL2 may be deposited thinner than the intermediate layer IL. In an embodiment, for example, the second protective layer PRL2 may be deposited to a thickness greater than or equal to about 400 angstrom (Å) and smaller than or equal to about 500 Å.

As a result, in the deposition step (S200), a mask body may be formed by depositing the first protective layer PRL1 surrounding the base substrate BS, the intermediate layer IL surrounding the first protective layer PRL1, and the second protective layer PRL2 surrounding the intermediate layer IL.

In the deposition step (S200), the first protective layer PRL1, the intermediate layer IL, and the second protective layer PRL2 may each be deposited as thin films using, for example, but not limited to, sputtering, physical vapor deposition, chemical vapor deposition, or atomic layer deposition.

The mask body may include a first side SF1 and a second side SF2 opposite to each other along a thickness direction of the mask body. When the deposition step (S200) is completed, the second protective layer PRL2 may be formed on both the first side SF1 and the second side SF2 of the mask body.

An embodiment of the method for manufacturing a deposition mask may further include a photolithography step between the deposition step (S200) and the pattern formation step (S300). In the photolithography step, photoresist may be coated onto the first side SF1 of the mask body, and exposure and development processes may be performed. As a result, a preliminary pattern for forming a pattern grid may be formed on the first side SF1 of the mask body.

Referring to FIGS. 6 and 7E, in the pattern formation step (S300), the second protective layer PRL2 and the intermediate layer IL formed on the first side SF1 of the mask body may be etched to form a pattern grid PGD. The second protective layer PRL2 and the intermediate layer IL may be etched using a dry etching process.

In the dry etching process, a Bosch process may be carried out by forming a CFₓ-based polymer such as C₄F₈ or CF₄ on the surface and sidewalls and etching with SF₆ plasma. In addition, deposition and etching may be performed repeatedly through the Bosch process. As a result, a high aspect ratio pattern may be formed, and the sidewalls being etched may be protected to prevent undercutting.

The Bosch process may be more suitable for etching an intermediate layer IL that includes at least one selected from monocrystalline silicon (Si) and polycrystalline silicon (Poly-Si) than for etching an intermediate layer IL that includes a low-stress nitride (LSN). Accordingly, in the pattern formation step (S300), the pattern grid PGD having a tapered shape may be formed by the Bosch process. An area of an upper surface of the pattern grid PGD adjacent to the first side SF1 of the mask body may be larger than an area of a lower surface of the pattern grid PGD adjacent to the base substrate BS.

The method of forming the pattern grid PGD in the pattern formation step (S300) is not limited to the above description. In another embodiment, a tapered pattern grid PGD may also be formed using other dry etching techniques other than the Bosch process.

Referring to FIGS. 6 and 7F, in the first etching step (S400), the second protective layer PRL2 and the intermediate layer IL formed on the second side SF2 of the mask body may be removed. The first etching step (S400) may be understood as a pretreatment step for forming a mask opening in the base substrate BS.

In the first etching step (S400), the first protective layer PRL1 formed on the second side SF2 of the mask body may be further removed. The first protective layer PRL1 may be removed using a dry etching process or a wet etching process.

Referring to FIGS. 6 and 7G, in the mask opening formation step (S500), the first protective layer PRL1 and the base substrate BS may be etched to form a mask opening overlapping the pattern grid PGD. In the mask opening formation step (S500), the mask opening may be formed using a wet etching process. The mask opening may be formed such that an area of an upper surface of the base substrate BS adjacent to the pattern grid PGD is larger than an area of a lower surface of the base substrate BS adjacent to the second side SF2 of the mask body. Accordingly, the mask opening may have an inverted taper shape in cross-section. The first protective layer PRL1 may be etched from both the upper and lower portions of the base substrate BS.

After the first protective layer PRL1 on the second side SF2 is removed in the first etching step (S400), in the mask opening formation step (S500), the first protective layer PRL1 remaining on the first side SF1 of the mask body may be etched. As a result, as shown in FIG. 7I, the deposition mask may not include the first protective layer PRL1 on the second side SF2 of the mask body.

Referring to FIGS. 6 and 7H, in the second etching step (S600), the second protective layer PRL2 remaining on the first side SF1 of the mask body may be removed. The second protective layer PRL2 that was not removed in the first etching step (S400) may be removed in the second etching step (S600). The second protective layer PRL2 may be removed using a wet etching process.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A deposition mask comprising:
a base layer having an opening defined therein corresponding to a transmission region;
a protective layer disposed on the base layer and having an opening defined therein overlapping the transmission region; and
a pattern layer disposed on the protective layer and comprising a pattern grid overlapping the transmission region,
wherein an area of a lower surface of the pattern grid adjacent to the protective layer is smaller than an area of an upper surface of the pattern grid opposite to the lower surface, and
wherein the pattern layer comprises at least one selected from monocrystalline silicon and polycrystalline silicon.

2. The deposition mask according to claim 1, wherein a width of the pattern grid increases as being away from the protective layer.

3. The deposition mask according to claim 2, wherein the base layer comprises silicon.

4. The deposition mask according to claim 3, wherein an area of an upper surface of the base layer adjacent to the protective layer is larger than an area of a lower surface of the base layer opposite to the protective layer with the upper surface of the base layer therebetween.

5. The deposition mask according to claim 1, wherein the protective layer comprises silicon oxide (SiOₓ).

6. The deposition mask according to claim 5, wherein an area of an upper surface of the protective layer adjacent to the pattern layer is larger than an area of a lower surface of the protective layer adjacent to the base layer.

7. The deposition mask according to claim 1, further comprising a lower layer disposed below the base layer and having an opening defined therein overlapping the transmission region.

8. The deposition mask according to claim 7, wherein the lower layer comprises silicon oxide (SiOₓ).

9. A method for manufacturing a deposition mask, the method comprising:
preparing a base substrate comprising silicon;
forming a mask body by depositing a first protective layer surrounding the base substrate, an intermediate layer surrounding the first protective layer and comprising at least one selected from monocrystalline silicon and polycrystalline silicon, and a second protective layer surrounding the intermediate layer;
forming a pattern grid by etching the second protective layer and the intermediate layer formed on a first side of the mask body;
performing a first etching process to remove the second protective layer and the intermediate layer formed on a second side of the mask body opposite to the first side with the base substrate therebetween;
forming a mask opening overlapping the pattern grid by etching the first protective layer and the base substrate from the second side; and
performing a second etching process to remove the second protective layer remaining on the first side.

10. The method for manufacturing a deposition mask according to claim 9, wherein the forming the pattern grid comprises dry etching the second protective layer and the intermediate layer using a Bosch etching process.

11. The method for manufacturing a deposition mask according to claim 10, wherein in the forming the pattern grid, the pattern grid is formed in a way such that an area of an upper surface of the pattern grid adjacent to the first side of the mask body is larger than an area of a lower surface of the pattern grid adjacent to the base substrate.

12. The method for manufacturing a deposition mask according to claim 11, further comprising, between the forming the mask body and the forming the pattern grid, coating photoresist onto the first side of the mask body and performing exposure and development processes.

13. The method for manufacturing a deposition mask according to claim 9, wherein the forming the mask opening comprises using a wet etching process.

14. The method for manufacturing a deposition mask according to claim 13, wherein in the forming the mask opening, the mask opening is formed in a way such that an area of an upper surface of the base substrate adjacent to the pattern grid is larger than an area of a lower surface of the base substrate adjacent to the second side of the mask body.

15. The method for manufacturing a deposition mask according to claim 9, wherein the second protective layer comprises silicon nitride (SiNₓ).

16. The method for manufacturing a deposition mask according to claim 15, wherein in the forming the mask body, the second protective layer is deposited to be thinner than the intermediate layer.

17. The method for manufacturing a deposition mask according to claim 16, wherein in the forming the mask body, the second protective layer is deposited to have a thickness greater than or equal to about 400 Å and smaller than or equal to about 500 Å.

18. The method for manufacturing a deposition mask according to claim 9, wherein the performing the first etching process comprises removing the first protective layer formed on the second side of the mask body, and
wherein the forming the mask opening comprises etching the first protective layer formed on the first side.

19. The method for manufacturing a deposition mask according to claim 9, wherein the performing the second etching process comprises removing the second protective layer using a wet etching process.

20. The method for manufacturing a deposition mask according to claim 9, wherein the first protective layer comprises silicon oxide (SiOₓ).
